(19) United States
(12) Patent Application Publication
(10) Pub. No.: US 2025/0102910 A1
(43) Pub. Date: Mar. 27, 2025

(54) PHOTORESIST COMPOSITION AND METALLIZATION METHOD

(71) Applicant: DuPont Electronic Materials International, LLC, Marlborough, MA (US)

(72) Inventor: Mitsuru Haga, Niigata (JP)

(21) Appl. No.: 18/222,666

(22) Filed: Jul. 17, 2023

(51) Int. Cl. G03F 7/004; C08F 212/14; G03F 7/038; G03F 7/039

(52) U.S. Cl. CPC G03F 7/0045; C08F 212/24; G03F 7/038; G03F 7/039

(57) ABSTRACT

Disclosed herein is a photoresist composition comprising a polymer comprising a first repeat unit of formula (3) and a second repeat unit of formula (4):

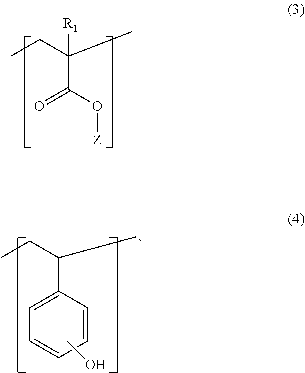

wherein: R₁ is a hydrogen atom or substituted or unsubstituted C₁-C₃ alkyl; Z is a non-hydrogen substituent comprising an acid-labile moiety; where m and n are the number of repeat units of the first repeat unit and second repeat unit respectively; a compound of formula (6):

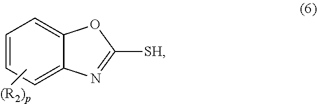

wherein: R₂ is independently C₁-C₃ alkyl or C₁-C₃ alkoxy; and p is an integer from 0 to 4; a photoacid generator; and a solvent.

### BACKGROUND

This disclosure relates to a photoresist composition and a metallization method. In particular, this disclosure relates to a photoresist composition that prevents the development of a footing profile in a photoresist pattern.

Mobile devices, devices that are part of the internet of things (IoT) and wearable electronics have over the years become smaller, lighter and thinner devices that despite increasing miniaturization use larger amounts of memory and perform increasingly larger amounts of computation.

The manufacture and packaging of these electronic devices serves an important role in the size reduction. For example, flip-chip packaging methods have been used to increase the density of I/O (Input/Output) connections between devices, especially for micro-processing unit (MPU) and dynamic random-access memory (DRAM) semiconductor chips.

Metal pillar bumps such as, for example, copper pillar bumps are often used as a flip chip interconnect for use in electronics and optoelectronic packaging, including: flip chip packaging of CPU and GPU integrated circuits (chips), laser diodes, and semiconductor optical amplifiers (SOA). Metal pillar bumps provide beneficial connection resistance, high-density connections, metal migration resistance, and thermal dissipation properties. Metal line patterns may also be used, for example in a re-distribution layer (RDL), for providing electrical connection between two components.

Electroplating has been used for the fabrication of metal pillar bump arrays and line patterns. A photoresist layer is coated on a copper film surface and a mask pattern is then manufactured using photolithography. Metal structures are then formed on the metal surface by electroplating in open areas of the mask pattern. The photoresist is then removed and the metal layer that was previously covered by the resist is removed by etching.

One approach to the preparation of plating mask patterns is the use of thick photoresist layers to respond to the need for thicker and narrower pattern sizes for further increases in I/O and device density. Chemically amplified photoresists may be a suitable option for achieving the faster sensitivity and improved transparency desired for higher resolution patterns. Such resist compositions include a polymer having acid labile groups, a photoacid generator (PAG), and a solvent. However, when chemically amplified resists are formed on a metal layer, such as a copper layer, footing profile issues have been observed due to loss of photoacid present at the interface between the metal surface and the resist.

The footing in the resist pattern results in an undercut profile in the plated pattern. This can promote collapse of the plated patterns during downstream processing. Thus, it is desired that footing of photoresist patterns used as plating masks is eliminated.

### SUMMARY

Disclosed herein is a photoresist composition comprising a polymer comprising a first repeat unit of formula (3) and a second repeat unit of formula (4):

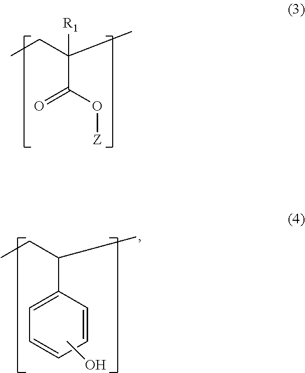

wherein: R₁ is a hydrogen atom or substituted or unsubstituted C₁-C₃ alkyl; Z is a non-hydrogen substituent comprising an acid-labile moiety; where m and n are the number of repeat units of the first repeat unit and second repeat unit respectively; a compound of formula (5):

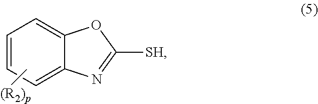

wherein: R₂ is independently C₁-C₃ alkyl or C₁-C₃ alkoxy; and p is an integer from 0 to 4; a photoacid generator; and a solvent.

Disclosed herein too is a photoresist composition comprising: (a) a polymer; (b) one or more photoacid generators; (c) a first base quencher; (d) a second base quencher; and (e) a solvent; wherein the polymer comprises the following two repeat units:

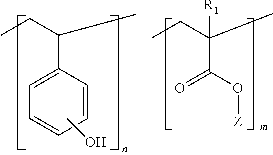

wherein: R₁ is a hydrogen atom or substituted or unsubstituted C₁-C₃ alkyl; Z is a non-hydrogen substituent that provides an acid-labile moiety; m is 20 to 90 mole % and n is 10 to 80 mole %, based on total polymerized units present in the polymer; wherein the photoacid generator is selected from N-hydroxynaphthalimide trifluoromethanesulfonate, N-hydroxynaphthalimide perfluoro-1-butanesulfonate, N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy) phthalimide and N-hydroxysuccinimide perfluorobutanesulfonate; wherein the first base quencher is selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino) propionate, 4-(p-tolyl) morpholine, or a combination thereof; wherein the second base quencher is a compound of formula (5):

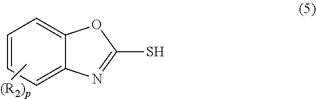

wherein: R₂ is independently C₁-C₃ alkyl or C₁-C₃ alkoxy; and p is an integer from 0 to 4; and wherein the solid content of the photoresist composition is from 10 to 60 wt %.

Disclosed herein too is a process comprising forming a photoresist layer on a metal layer, wherein the photoresist layer comprises: (a) a polymer, (b) a photoacid generator, (c) a first base quencher, and (d) a second base quencher; patternwise exposing the photoresist layer to activating radiation; and contacting the photoresist layer with an alkaline developing solution to remove exposed portions of the photoresist layer; and immersing the metal layer in a metal plating solution and depositing a metal on the metal layer in the exposed portions of the photoresist layer; wherein the polymer comprises the following two repeat units:

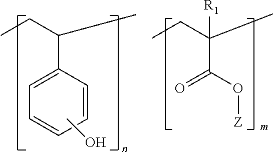

wherein: R₁ is a hydrogen atom or substituted or unsubstituted C₁-C₃ alkyl; Z is a non-hydrogen substituent that provides an acid-labile moiety; m is 20 to 90 mole % and n is 10 to 80 mole %, based on total polymerized units present in the polymer; and the first base quencher is selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino) propionate, 4-(p-tolyl) morpholine, or a combination thereof; and the second base quencher is a compound of formula (5):

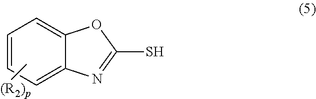

wherein: R₂ is independently C₁-C₃ alkyl or C₁-C₃ alkoxy; and p is an integer from 0 to 4.

### BRIEF DESCRIPTION OF THE FIGURES

FIG. 1A depicts an exemplary embodiment of the substrate upon which at first metal layer is disposed;

FIG. 1B depicts an exemplary embodiment of the deposition of the photoresist layer on the first metal layer and the photopatterning of the photoresist layer and the first metal layer;

FIG. 1C depicts an exemplary embodiment of the development of the photoresist layer;

FIG. 1D is an exemplary depiction of the deposition of metal (via plating) on the metal layer;

FIG. 1E depicts the plated metal structures left behind after removal of the remaining photoresist layer;

FIG. 2 depicts Table 1, which includes data from the working examples;

FIG. 3 depicts Table 3, which includes data from the working examples;

FIG. 4 is a graph of the optimum exposure energy to nominal pattern size (Eop) directed to the photoresist composition versus the molar ratio of the second base quencher to the PAG contained in the respective compositions;

FIG. 5 is a depiction of weight loss of the each of the second base quenchers as determined using thermogravimetric analysis; and

FIG. 6 depicts Table 5, which includes data from the working examples.

### DETAILED DESCRIPTION

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise.

As used herein, an “acid-labile group” refers to a group in which a bond is cleaved by the catalytic action of an acid, optionally and typically with thermal treatment, resulting in a polar group, such as a carboxylic acid or an alcohol group, being formed on the polymer, and optionally and typically with a moiety connected to the cleaved bond becoming disconnected from the polymer. Such acid is typically a photo-generated acid with bond cleavage occurring during post-exposure baking. Suitable acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

Disclosed herein is a photoresist composition that reduces footing in a photoresist layer when used as a plating mask. The photoresist composition comprises a polymer that comprises an acid-labile group; a first base quencher; a second base quencher; and a photoacid generator. Disclosed herein too is a method for manufacturing semiconductors that minimizes the occurrence of footing in the photoresist layer during the manufacturing process. Footing causes an undercut of a plated pattern, which may promote a collapsing of the plated pattern during further process and reliability testing. It is therefore desirable to eliminate or to minimize footing of the plated pattern.

The aforementioned photoresist composition is disposed on a substrate to form a photoresist layer. The photoresist layer is patternwise exposed to activating radiation. The exposed photoresist layer is then developed with a basic developer, thereby removing portions of the photoresist layer to form a relief pattern. A metal may be plated on the first surface of the substrate after forming the relief pattern.

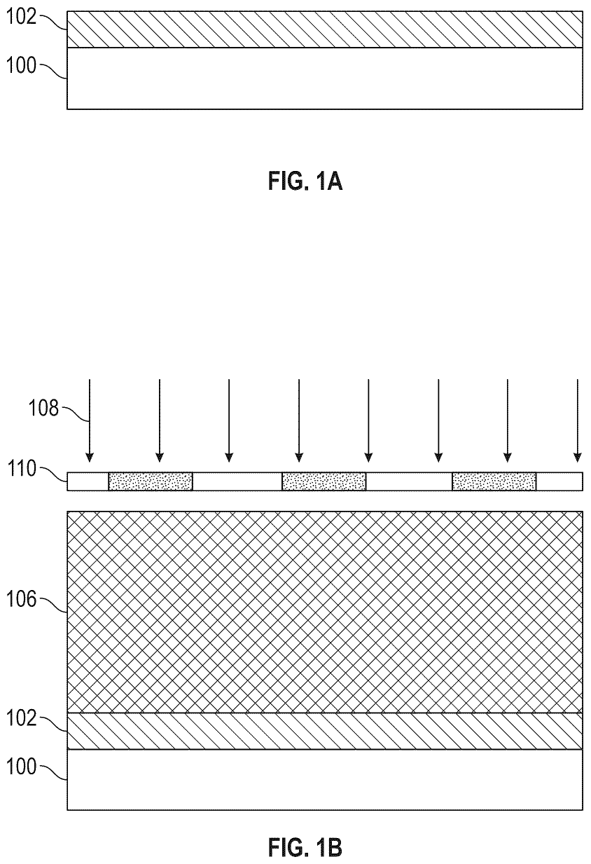

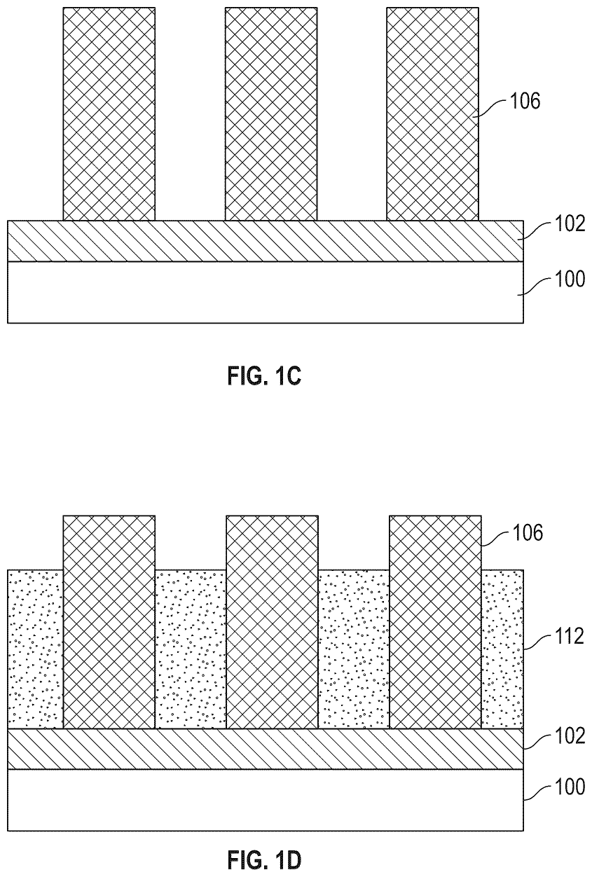

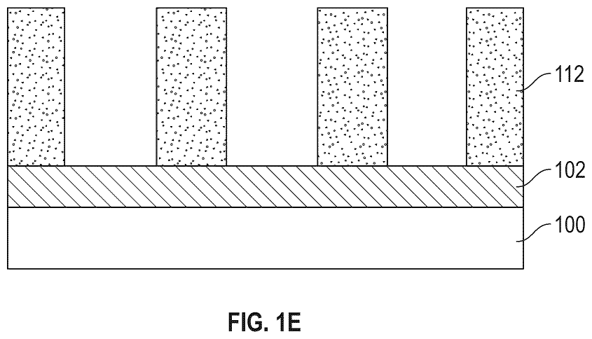

FIGS. 1A-1E depict a method of forming a plated pattern on a substrate. FIG. 1A depicts the substrate 100 upon which at first metal layer 102 is disposed. FIG. 1B depicts the coating of the photoresist layer 106 on the metal layer 102 followed by photo-exposure of the photoresist layer 106. The photoresist layer 106 comprises a photoacid generator and a polymer that contains an acid labile group. After coating the photoresist layer 106, the photoresist layer 106 is patternwise exposed to activating radiation 108 through a photomask 110 having optically opaque and optically transparent regions. A UV light having a wavelength of 10 to 400 nanometers may be used in the photopatterning.

FIG. 1C depicts the development of the exposed parts of the photoresist layer 106. The exposed portions of the photoresist layer 106 are removed via development as seen in the FIG. 1C. After metal plating as seen in FIG. 1D, the remaining portions of the photoresist layer can be removed (stripped) from the substrate to leave behind the plated metal structures 112. FIG. 1E depicts the plated metal structures 112 left behind after removal of the remaining photoresist layer.

The various layers (depicted in the FIGS. 1A-1E) and their respective compositions described above will now be described in detail.

### The Substrate

Examples of the substrate include, but are not limited to, silicon wafers, glass substrates and plastic substrates, such substrates optionally including one or more layers or features formed thereon. A preferred substrate is a silicon wafer.

### The Metal Layer

FIG. 1A depicts the substrate 100 upon which at first metal layer 102 is disposed. An optional second metal layer (not shown) may be disposed on the first metal layer 102. The first metal layer can be made, for example, of titanium, silver, aluminum, gold, copper, or an alloy thereof. In an exemplary embodiment, the first metal layer 102 comprises titanium or copper. When a second metal layer is disposed on the first metal layer, the first metal layer preferably comprises titanium. The metal first layer can be formed using known methods, for example, by chemical vapor deposition (CVD), plasma enhanced chemical vapor deposition (PECVD) or physical vapor deposition (PVD) techniques, with sputtering and plating being typical. The thickness of the first metal layer 102 is typically from 10 nm to 500 nm.

The optional second metal layer comprises tantalum, titanium, copper, silver, aluminum, gold, or an alloy thereof. The second metal layer is chemically different from the first metal layer 102. In an exemplary embodiment, the second metal layer comprises copper. The second metal layer may be disposed on the surface of the first metal layer via chemical vapor deposition (CVD), plasma enhanced chemical vapor deposition (PECVD), physical vapor deposition (PVD), or a combination thereof. The thickness of the second metal layer is typically from 10 nm to 500 nm.

### The Photoresist Layer

FIG. 1B depicts the deposition of the photoresist layer 106 on the first metal layer 102. The photoresist composition 106 comprises a polymer that comprises an acid-labile group; a photoacid generator; a first base quencher and a second base quencher. The polymer comprises first repeat units that comprise an acid labile group. In an embodiment, the polymer comprises second repeat units that comprise a vinyl aromatic group.

The acid labile group is a chemical moiety that undergoes a deprotection reaction in the presence of an acid. Deprotection of some acid labile groups that are used in the examples are brought on by heat. Acetal protection groups readily undergo deprotection at room temperature. The polymer of the photoresist composition undergoes a change in solubility in a developer as a result of reaction with acid generated from the photoacid generator (included in the photoresist composition) following soft bake, exposure to activating radiation and post exposure bake. This results from photoacid-induced cleavage of the acid labile group causing a change in polarity of the polymer. The acid labile group can be chosen, for example, from tertiary alkyl carbonates, tertiary alkyl esters, tertiary alkyl ethers, acetals and ketals. Preferably, the acid labile group is an ester group that contains a tertiary non-cyclic alkyl carbon or a tertiary alicyclic carbon covalently linked to a carboxyl oxygen of an ester of the polymer. The cleavage of such acid labile groups results in the formation of carboxylic acid groups.

In one embodiment, the polymer that comprises the acid-labile group includes polymerized units having the structure shown in formula (1) below:

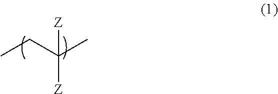

wherein Z is selected from a hydrogen atom, substituted or unsubstituted C₁-C₄ alkyl, substituted or unsubstituted C₁-C₄ fluoroalkyl or a cyano group; Z¹ is a non-hydrogen substituent comprising an acid-labile group, the cleavage of which forms a carboxylic acid on the polymer.

In an embodiment, the acid-labile group which, on decomposition, forms a carboxylic acid group on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—or —S—, and one R² together with R³ optionally forming a ring. Such monomer is typically a vinyl aromatic, (meth) acrylate, or norbornyl monomer.

Suitable acid labile-group containing units include, for example, acid-labile (alkyl)acrylate units, such as t-butyl (meth)acrylate, 1-methylcyclopentyl (meth)acrylate, 1-ethylcyclopentyl (meth)acrylate, 1-isopropylcyclopentyl (meth)acrylate, 1-propylcyclopentyl (meth)acrylate, 1-methylcyclohexyl (meth)acrylate, 1-ethylcyclohexyl (meth)acrylate, 1-isopropylcyclohexyl (meth)acrylate, 1-propylcyclohexyl (meth)acrylate, methyladamantyl(meth)acrylate, ethyladamantyl(meth)acrylate, and the like, and other cyclic, including alicyclic, and non-cyclic (alkyl) acrylates.

Acetal and ketal acid labile groups can be substituted for the hydrogen atom at the terminal of an alkali-soluble group such as a carboxyl group so as to be bonded with an oxygen atom. When acid is generated, the acid cleaves the bond between the acetal or ketal group and the oxygen atom to which the acetal-type acid-dissociable, dissolution-inhibiting group is bonded. Exemplary such acid labile groups are described, for example, in U.S. Pat. Nos. 6,057,083, 6,136,501 and 8,206,886 and European Pat. Pub. Nos. EP01008913A1 and EP00930542A1. Also suitable are acetal and ketal groups as part of sugar derivative structures, the cleavage of which would result in the formation of hydroxyl groups, for example, those described in U.S. Patent Application No. US2012/0064456A1.

Suitable polymers include, for example, phenolic resins that contain acid-labile groups. Particularly preferred resins of this class include: (i) polymers that contain polymerized units of a vinyl phenol and an acid labile (alkyl) acrylate as described above, such as polymers described in U.S. Pat. Nos. 6,042,997 and 5,492,793; (ii) polymers that contain polymerized units of a vinyl phenol, an optionally substituted vinyl phenyl (e.g., styrene) that does not contain a hydroxy or carboxy ring substituent, and an acid labile (alkyl) acrylate such as described above, such as polymers described in U.S. Pat. No. 6,042,997; (iii) polymers that contain repeat units that comprise an acetal or ketal moiety that will react with photoacid, and optionally aromatic repeat units such as phenyl or phenolic groups; such polymers described in U.S. Pat. Nos. 5,929,176 and 6,090,526, and blends of (i) and/or (ii) and/or (iii). Such polymers are useful for imaging at wavelengths, for example, of 200 nm or greater, such as 248 nm and 365 nm.

Suitable polymers include those that are useful for imaging at certain sub-200 nm wavelengths such as 193 nm, such as those disclosed in European Patent Publication No. EP930542A1 and U.S. Pat. Nos. 6,692,888 and 6,680,159. For imaging at 193 nm wavelength, the polymers are preferably substantially free (e.g., less than 15 mole %), preferably completely free of phenyl, benzyl or other aromatic groups where such groups are highly absorbing of the radiation.

Other suitable polymers for use in the photoresist composition include, for example, those which contain polymerized units of a non-aromatic cyclic olefin (endocyclic double bond) such as an optionally substituted norbornene, for example, polymers described in U.S. Pat. Nos. 5,843,624 and 6,048,664. Still other suitable polymers for use in the photoresist composition include polymers that contain polymerized anhydride units, particularly polymerized maleic anhydride and/or itaconic anhydride units, such as disclosed in European Published Application EP01008913A1 and U.S. Pat. No. 6,048,662.

Also suitable for use in the photoresist composition is a polymer that contains repeat units that contain a hetero atom, particularly oxygen and/or sulfur (but other than an anhydride, i.e., the unit does not contain a keto ring atom). The heteroalicyclic unit can be fused to the polymer backbone and can comprise a fused carbon alicyclic unit such as provided by polymerization of a norbornene group and/or an anhydride unit such as provided by polymerization of a maleic anhydride or itaconic anhydride. Such polymers are disclosed in International Pub. No. WO0186353A1 and U.S. Pat. No. 6,306,554. Other suitable hetero-atom group containing polymers include polymers that contain polymerized carbocyclic aryl units substituted with one or more hetero-atom (e.g., oxygen or sulfur) containing groups, for example, hydroxy naphthyl groups, such as disclosed in U.S. Pat. No. 7,244,542.

The polymer may further include a unit that contains a lactone moiety for controlling the dissolution rate of the polymer and the photoresist composition. Suitable monomers for use in the polymer containing a lactone moiety include, for example, the following:

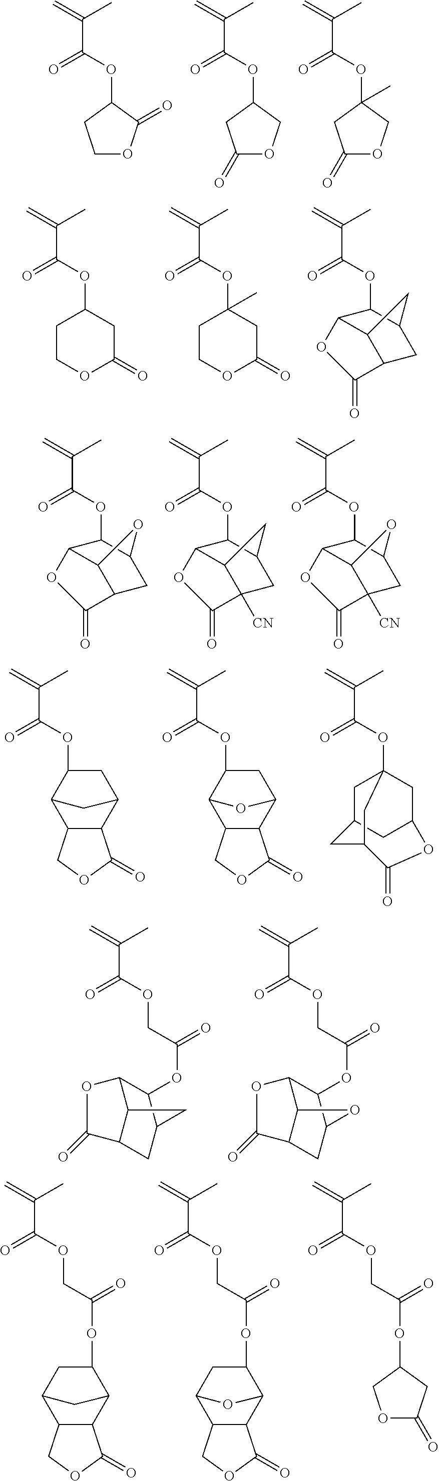

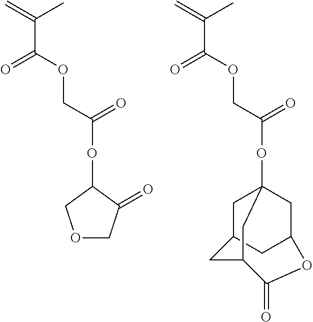 [SMILES: C=C(C)C(=O)OCC(=O)OC1COCC1=O ; C=C(C)C(=O)OCC(=O)OC12CC3CC(C1)OC(=O)C(C3)C2]

In an embodiment, the polymer further typically includes a unit containing a polar group, which enhances etch resistance of the polymer and photoresist composition and provides additional means to control the dissolution rate of the polymer and photoresist composition. Monomers for forming such a unit include, for example, the following:

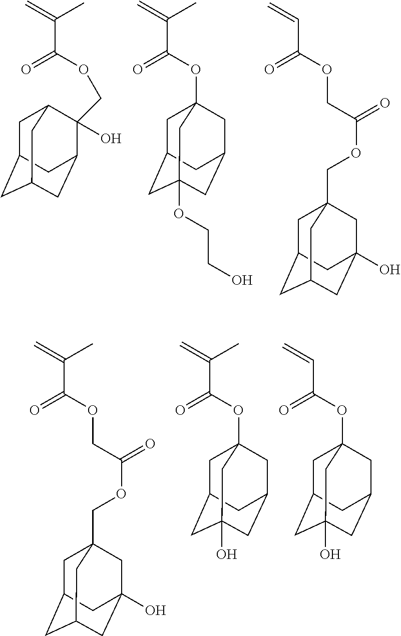

The polymer can include one or more additional units of the types described above. Typically, the additional units for the polymer will include the same or similar polymerizable group as those used for the monomers used to form the other units of the polymer, but may include other, different polymerizable groups in the same polymer backbone.

The polymer may also include one or more repeat units derived from the polymerization of a vinyl aromatic monomer. An exemplary vinyl aromatic monomer is styrene. In an embodiment, a polymer derived from a vinyl aromatic monomer has the structure shown in formula (2) below:

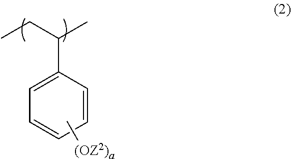

wherein a is 1 to 5 and where Z² is a hydrogen or an alkyl group having 1 to 5 carbon atoms. In a preferred embodiment, a is 1 and Z² is hydrogen. It is preferable for the vinyl aromatic monomer to have a hydroxyl group located in the para-position on the aryl ring. A preferred vinyl aromatic polymer is poly (p-hydroxystyrene) (abbreviated as PHS).

In an embodiment, the polymer for use in the photoresist composition comprises a first repeat unit of formula (3) and a second repeat unit of formula (4):

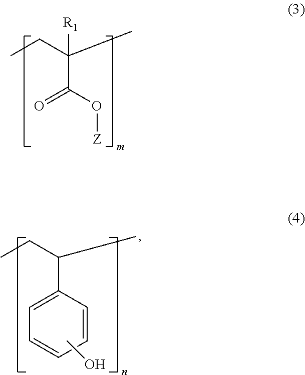

wherein: R₁ is a hydrogen atom or substituted or unsubstituted C₁-C₃ alkyl; Z is a non-hydrogen substituent comprising an acid-labile moiety. In an embodiment, m+n (in formulas (3) and (4)) is 70 to 100 mole percent (mole %). In an embodiment, m is 10 to 90 mole %, preferably 25 to 80 mole %, preferably 30 to 40 mole %, and n is 10 to 90 mole %, preferably 20 to 70 mole % based on total polymerized units present in the polymer. In an embodiment, the mole ratio of n to m is 0.11 to 9, preferably 0.2 to 4.

When the polymer comprises third repeat units (that are different from the first repeat units and the second repeat units), the third repeat units may be present in the polymer in an amount of 5 to 35 mole % and preferably 10 to 30 mole %, based on total polymerized units present in the polymer.

While not to be limited thereto, exemplary polymers include, for example, the following:

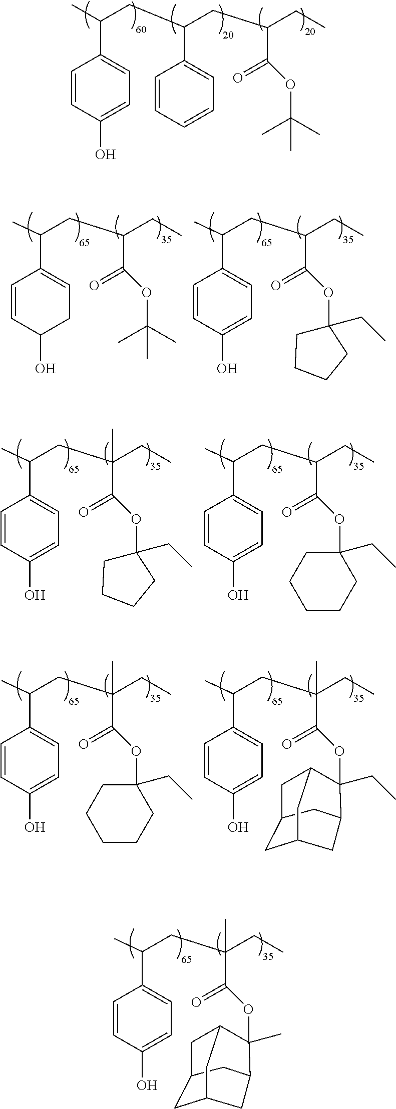

Suitable polymers for use in the photoresist compositions are commercially available and can readily be made by persons skilled in the art. The polymer is present in the photoresist composition in an amount sufficient to render an exposed coating layer of the photoresist developable in a suitable developer solution.

Typically, the polymer is present in the photoresist composition in an amount of from 70 to 100 wt % based on total solids of the photoresist composition. The weight average molecular weight M_{w} of the polymer is typically less than 100,000, for example, from 4000 to 100,000, more typically from 4000 to 20,000 grams per mole (g/mole) as measured by gel permeation chromatography using a polystyrene standard. Blends of two or more of the above-described polymers can suitably be used in the photoresist composition of the invention.

The photoresist composition comprises a non-ionic photoacid generator. In an embodiment, the photoresist composition may optionally contain an ionic photoacid generator. It is desirable to use photoacid generators that generate the photoacid by a Norrish-1 cleavage. The Norrish-I reaction is the photochemical cleavage or homolysis of aldehydes and ketones into two free radical intermediates. The carbonyl group accepts a photon and is excited to a photochemical singlet state. In an embodiment, the photoacid generator has the structure shown in formula (5)

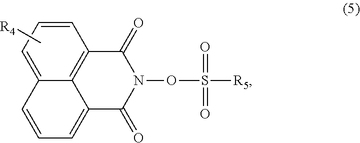

wherein in formula (4), R₄ is a hydrogen atom, a substituted or unsubstituted, linear or branched C₁ to C₁₄ alkyl group, a substituted heterocyclic group, or a halogen atom; and wherein R₅ is a substituted or unsubstituted alkyl group having 1 to 18 carbon atoms; a halogen atom, or an aryl group having 6 to 20 unsubstituted carbon atoms.

Examples of suitable photoacid generators are N-hydroxynaphthalimide trifluoromethanesulfonate (NHNI-TF), N-hydroxynaphthalimide perfluoro-1-butanesulfonate (NHNI-PFBS), N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy)phthalimide, N-hydroxysuccinimide perfluorobutanesulfonate or benzeneacetonitrile, 2-methyl-α-[2-[[(propylsulfonyl)oxy]imino]-3(2H)-thienylidene]-(commercially available as IRGACURE PAG 103). In a preferred embodiment, the photoacid generator may be one or more of the structures of formulas (5a) or (5b) shown below

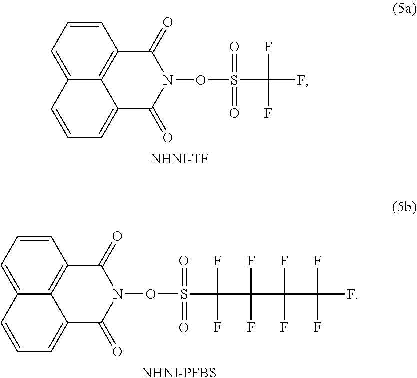

The photoacid generator is present in the photoresist composition in an amount of from 0.2 to 15 wt %, more typically 0.3 to 5 wt %, and more preferably 0.5 to 2 wt %, based on total solids of the photoresist composition.

As noted above, the photoresist composition comprises a first base quencher and a second base quencher. The base quenchers enhance the resolution of the developed resist relief image. The first base quencher is preferably a weaker base than a common tertiary amine. The lower basicity prevents decomposition of the i-line sensitive photoacid generator during the storage of the photoresist composition. The first base quencher is selected from the group consisting of N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino) propionate, 4-(p-tolyl) morpholine, or a combination thereof.

The first base quencher is preferably added in an amount effective to render the photoresist composition with a pKa of less than 7. The amount of the first base quencher in the photoresist layer is preferably from 0.001 to 1.0 wt %, more preferably from 0.01 to 0.8 wt % or from 0.02 to 0.2 wt % based on the total weight of solids in the photoresist composition.

The second base quencher comprises a 2-mercapto aromatic azole analog. In an embodiment, the aromatic azole analog comprises a thiol functional unit in the 2^{nd} position of the aromatic azole compound. If the 2^{nd} position is replaced with a chemical moiety other than a thiol, such as, for example, a methyl-thio or carboxy-methyl-thio moiety, it does not improve the footing profile on the copper substrate.

Examples of the aromatic azole analog include benzoxazoles. An example of a benzoxazole that may be used as the second base quencher includes a compound of formula (6):

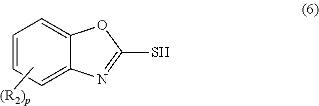

wherein: R₂ is independently C₁-C₃ alkyl or C₁-C₃ alkoxy; and p is an integer from 0 to 4. The amount of the second base quencher is 0.01 wt % to 1 wt %, based on the total weight of solids in the photoresist composition. A loading of the second base quencher in an amount greater than 1 wt % (a loading that exceeds chemisorption layer formation) may affect the angled pattern profile when viewed across the cross-section.

The photoresist composition further comprises a solvent. The solvent is used to solvate the polymer and to facilitate miscibility of the various ingredients used in the composition.

Solvents generally suitable for dissolving, dispensing, and coating include anisole, alcohols including 1-methoxy-2-propanol (also referred to as propylene glycol methyl ether, PGME), and 1-ethoxy-2 propanol, esters including n-butyl acetate, 1-methoxy-2-propyl acetate (also referred to as propylene glycol methyl ether acetate, PGMEA), methoxyethyl propionate, ethoxyethyl propionate, ketones including cyclohexanone, 2,6-dimethyl-4-heptanone, 2 heptanone; ethyl lactate (EL), 2-hydroxyisobutyric acid methyl ester (HBM), gamma-butyrolactone (GBL), 3-methoxypropanoic acid methyl ester, and combinations thereof.

The solvent amount can be, for example, 25 to 1900 wt %, preferably 67 to 900 wt %, and more preferably 100 to 150 wt %, based on the total weight of the solids of the photoresist composition. It will be understood that “polymer” used in this context of a component in the photoresist layer may mean only the polymers (that contain the acid labile group) disclosed herein. It will be understood that total solids include the polymer, photo destroyable base, quencher, surfactant, photoacid generator, and any optional additives, exclusive of solvent. The solids content of the composition may be 5 to 80 wt %, preferably 10 to 60 wt %.

The photoresist composition can comprise other optional ingredients, such as one or more surface leveling agent (SLA), adhesion promoter and/or plasticizer. If used, the SLA is preferably present in an amount of from 0.001 to 0.1 wt %, based on total weight of solids of the photoresist composition, and if used, the adhesion promoter and/or plasticizer each are present in an amount of from 0.1 to 10 wt %, based on total weight of solids of the photoresist composition.

The photoresist composition is applied to the first metal layer 102 to form the photoresist layer 106. In an embodiment, the photoresist layer has a thickness of greater than 2 micrometers. The photoresist composition is generally applied upon a surface of the metal layer via spin-coating, dipping, roller-coating or some other conventional coating technique. Spin-coating is preferred. For spin-coating, the solids content of the coating solution can be adjusted to provide a desired film thickness based upon the specific coating equipment utilized, the viscosity of the solution, the speed of the coating tool and the amount of time allowed for spinning. In an embodiment, the photoresist composition is applied in a single application.

The photoresist composition layer is then patternwise exposed to activating radiation through a photomask to create a difference in solubility between exposed and unexposed regions. With reference to the FIG. 1B, after the deposition of the photoresist layer 106, a mask 110 is disposed on the photoresist layer 106 in order to photo-pattern the photoresist layer 106. A UV light having a wavelength of 10 to 500 nanometers may be used in the photopatterning. The exposed portions of the photoresist layer may be removed by a suitable alkaline developer as seen in the FIG. 1C.

References herein to exposing a photoresist composition layer to radiation that is activating for the layer indicates that the radiation is capable of forming a latent image in the layer. The photomask has optically transparent and optically opaque regions corresponding to regions of the resist layer to be exposed and unexposed, respectively, by the activating radiation. The exposure wavelength is typically sub-500 nm, such as from 200 to 500 nm of UV-visible light. Preferably, the exposure is conducted with radiation of 365 nm wavelength from a mercury lamp (i-line).

Following exposure of the photoresist composition layer, a post exposure bake (PEB) is typically performed to decompose the acid labile group by acid that generated from the PAG during the exposure step. The PEB can be conducted, for example, on a hotplate or in an oven. A latent image defined by the boundary between polarity-switched and unswitched regions (corresponding to exposed and unexposed regions, respectively) is thereby formed.

The photoresist composition layer is next contacted with an alkaline developing solution to remove exposed portions of the layer, leaving unexposed regions forming a resist pattern. The developer is typically an aqueous alkaline developer, for example, a quaternary ammonium hydroxide solution, for example, a tetra-alkyl ammonium hydroxide solutions such as 0.26 Normality (N) (2.38 wt %) tetramethylammonium hydroxide (TMAH).

A further aspect is a process for depositing a metal on a metal layer 102. FIG. 1D is an exemplary depiction of the deposition of metal (via plating) 112 on the metal layer 102. The process includes immersing the metal layer in a metal plating solution and electro depositing a metal on the metal layer in the exposed portions of the photoresist composition layer. The metal layer 112 is typically formed on a substrate or on exposed portions of the first metal layer 102.

The substrate with the patterned photoresist layer 106 can be immersed in a metal plating solution to plate metal on the exposed first metal layer in those regions in which the photoresist composition layer has been developed away. The developed regions of the photoresist composition layer function as a mold for the metal plating. The metal can be plated, for example, by electroplating. Various types of metal plating solutions known in the art can be used. Also, two or more different layers of metal can be formed, and the layers can be of the same or different metals. Preferable plated metals include, but are not limited to, copper, nickel, tin, silver, gold and mixtures and alloys thereof. Suitable metal plating solutions for use in forming such metals are known in the art and are sourced from DuPont Electronics & Industrial. The thickness of the plated metal layer is typically from 1 to 100 micrometers, preferably from 5 to 50 micrometers. The plated metal layer thickness can be less than or exceed the thickness of the photoresist layer.

After metal plating, the remaining photoresist layer can be removed (stripped) from the substrate to leave behind the plated metal structures 112. FIG. 1E depicts the plated metal structures 112 left behind after removal of the remaining photoresist layer. Suitable photoresist strippers are sourced from, for example, DuPont Electronics & Industrial.

The exposed first metal layer between the plated metal structures can optionally be removed, for example, by etch-back process, to electrically isolate each of the plated metal structures. The obtained metal structures can have, for example, a line shape, which can be useful for re-distribution layer for providing electrical connection between two components. Advantageously, metal lines having small-width and straight (vertical) sidewalls can be formed by compositions and methods disclosed herein. Such structures find use, for example, in electrical connections in small, light and thin devices. The width of the lines can, for example, be from 0.8 to 100 micrometers, preferably from 1 to 50 micrometers. The height of the lines will depend, for example, on the thickness of the photoresist composition resin, but pillar heights of 2 micrometers or more can be formed.

This invention is advantageous in that the photoresist composition may be used to obtain lines with a larger cross-sectional area at the base when compared with the cross-sectional area at the top of the pillar. The use of the disclosed photoresist composition prevents the formation of an undercut at the bottom of the metal lines. This prevents crushing of the lines during further processing of the semiconductor.

The invention will now be exemplified by the following non-limiting examples.

### EXAMPLES

### Example 1

This example is conducted to demonstrate the using a photoresist composition that comprises a first base quencher and a second base quencher, where the second base quencher comprises an azole that reduces footing. It was also conducted to determine which particular substituents and the location of those substituents that would have a pronounced effect on the footing profile. The examples demonstrate which particular azole analog may be used to minimize footing in the photoresist layer.

The photoresist composition (used in this example) comprises a polymer that comprises a repeat unit having an acid labile group, a repeat unit that comprises a hydroxystyrene and a repeat unit that comprises styrene as seen in the formula (7) below. The polymer comprises a copolymer of poly(4-hydroxystyrene) in an amount of 70 mol %, polystyrene in an amount of 10 mol % and poly(tertbutyl acrylate) in an amount of 20 mol %, based on total polymerized units present in the polymer.

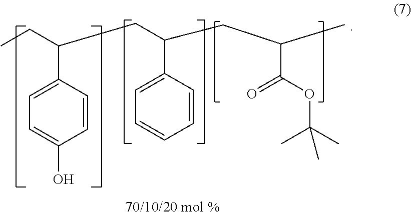

The polymer shown in formula (7) has a weight average molecular weight of 21,700 grams per mole, which was determined using a styrene standard.

NHNI-TF (methanesulfonic acid, 1,1,1-trifluoro-,1,3-dioxo-1H-benz[de]isoquinolin-2(3H)-yl ester) and NHNI-PFBS (1,3-dioxo-1H-benzo[de]isoquinolin-2(3H)-yl 1,1,2,2,3,3,4,4,4-nonafluorobutane-1-sulfonate) (Toyo Gosei Co.), both of which are shown below were used as photoacid generators (PAGs). The first base quencher is Troger's Base (2,8-dimethyl-6H,12H-5,11-Methanodibenzo[b,f][1,5]diazocine) (WAKO Fuji Film Co.) It was diluted to a 1 wt % solution in PGMEA. It was then filtered with a 0.45 μm PTFE filter to remove any insoluble impurities.

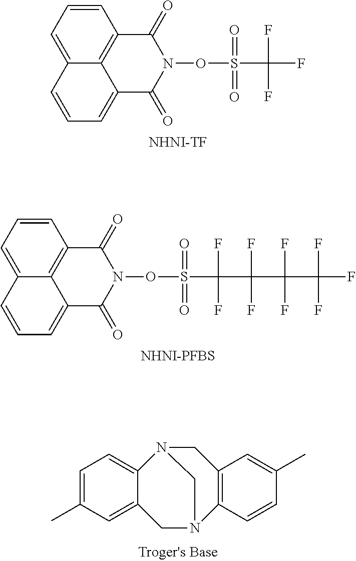

A plasticizer LUTONAL™ M40 (poly vinyl ethyl ether) (BASF Japan Co.) and a surface levelling agent (SLA) POLYFOX™PF-656 (OMNOVA Solutions Inc.) were provided. PGMEA (propylene glycol monoethyl acetate), PGME (1-methoxy-2-propanol,) and gamma butyrolactone were mixed together and used as a solvent in the photoresist compositions. Ingredients were disposed in a polypropylene bottle and stirred using a roller shaker (Roller Digital 10, IKA® Japan K.K.) over-night at a rotational speed of 10 rpm. After dissolution of ingredients was confirmed, filtration was conducted using a 10 μm pore-size PTFE membrane filter.

The composition for each sample is indicated in each section in the respective (formulation) tables. The weight of PAG, base quenchers and other additives such as SLA, plasticizer, solvents and other ingredients are indicated as a part by weight (pbw) against 100 parts of polymer. In addition, the loading level of the second base quencher(s) is also indicated as molar ratio of PAG.

A 150 nm thick titanium layer was deposited on 150 mm silicon substrates. A 200 nm thick copper layer was then deposited on the titanium layer by sputtering. The surface of the copper layer was washed using a solution of 10 wt % sulfuric acid (H₂SO₄) for 30 seconds to remove the surface oxidation layer, followed by a deionized (DI) water rinse. The water was then removed by blowing a stream of pressurized nitrogen onto the substrate. The substrate was puddle coated with a 2.38 wt % TMAH solution for 60 seconds, followed by a deionized water rinse. The substrate was then spin-dried.

The photoresist composition was then spin coated on the copper layer using a Sokudo D-Spin 60A SK-W60A-AVP wafer track. The spin speed was adjusted to obtain a 50 micrometer (μm) thick photoresist layer after a 135° C. soft-bake for 6 minutes.

The photoresist layer was then subjected to broad-band UV exposure on a Dainippon Kaken MA-1200 proximity mask aligner using a multi-tone exposure mask having square contact hole patterns with various dimensions. A post exposure bake (PEB) at 90° C. was conducted for 3 minutes.

The exposed photoresist layer was then puddle developed 4 times for 60 seconds each with a 2.38 wt % TMAH aqueous developer (MF® CD-26, DuPont Electronics & Industrial). Following the developing, the substrate was then rinsed with water and spin-dried.

The contact hole width was measured from a top view image taken using an optical microscope (H300, Lasertec using LIBRA software). Cross-sectional images of the contact hole were obtained using scanning electron microscopy to determine the amount of footing that occurs. The image was captured at a magnification of 50×.

### Example 2

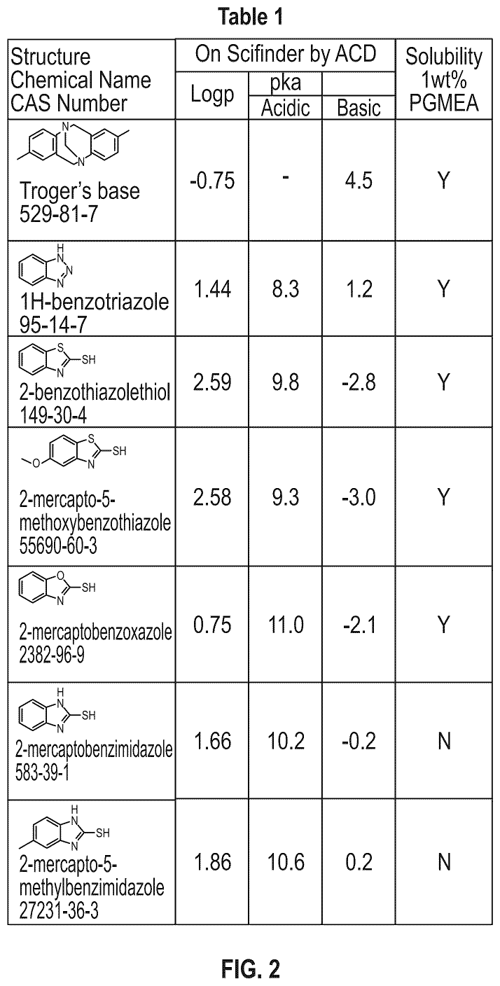

Solubility of the compounds shown in Table 1 in FIG. 2 was determined by human eye using 1 wt % solutions in PGMEA. The pKa values were taken from SciFinder n+.

Table 2 shows different formulations of the photoresist composition that were evaluated to determine which second base quencher displayed a useful sensitivity. All of the samples in Table 2 used Troger's base as the first base quencher. From Table 2 below it may be seen that Samples #1 to 3 used 2-mercapto 5-methoxy benzothiazole (MBT) as the second base quencher, while Samples #4-6 used 2-mercapto benzoxazole (MBO) as the second base quencher. The samples #7-9 used benzotriazole as the quencher. The molar ratio of the second base quencher to the PAG was varied from 0.09 to 0.21 to 0.33. Two PAGs were used—notably NHNI-PFBS and NHNI-TF in amounts 0.41 and 0.29 parts by weight per 100 parts by weight of the polymer. Samples #1-#3 and #7-#9 are comparative examples, while samples #4 to #6 exemplify the invention.

TABLE 2

| | Sample | Sample | Sample | | | | Sample | Sample | Sample |
|---|---|---|---|---|---|---|---|---|---|
| | #1 | #2 | #3 | Sample | Sample | Sample | #7 | #8 | #9 |
| Samples | (Comp) | (Comp) | (Comp) | #4 | #5 | #6 | (Comp) | (Comp) | (Comp) |
| Polymer | 100 pbw | | | | | | | | |
| PAG | NHNI-PFBS: 0.41 pbw/NHNI-TF: 0.29 pbw | | | | | | | | |
| 1^{st} Base | Troger's Base = 0.038 pbw | | | | | | | | |
| 2^{nd} Base | 2-mercapto 5-methoxy | | | 2-mercaptobenzoxazole | | | benzotriazole | | |
| [pbw] | benzothiazole (MBT) | | | (MBO) | | | (BTA) | | |
| | 0.030 | 0.069 | 0.108 | 0.023 | 0.053 | 0.083 | 0.018 | 0.042 | 0.065 |
| 2^{nd} Base/ | 0.09 | 0.21 | 0.33 | 0.09 | 0.21 | 0.33 | 0.09 | 0.21 | 0.33 |
| PAG mol | | | | | | | | | |
| ratio | | | | | | | | | |

| | |
|---|---|
| Plasticizer | LUTONAL ™ M40 = 1.0 pbw |
| Solvent | PGMEA: 130 pbw, GBL: 3 pbw |

Comp = Comparative Example

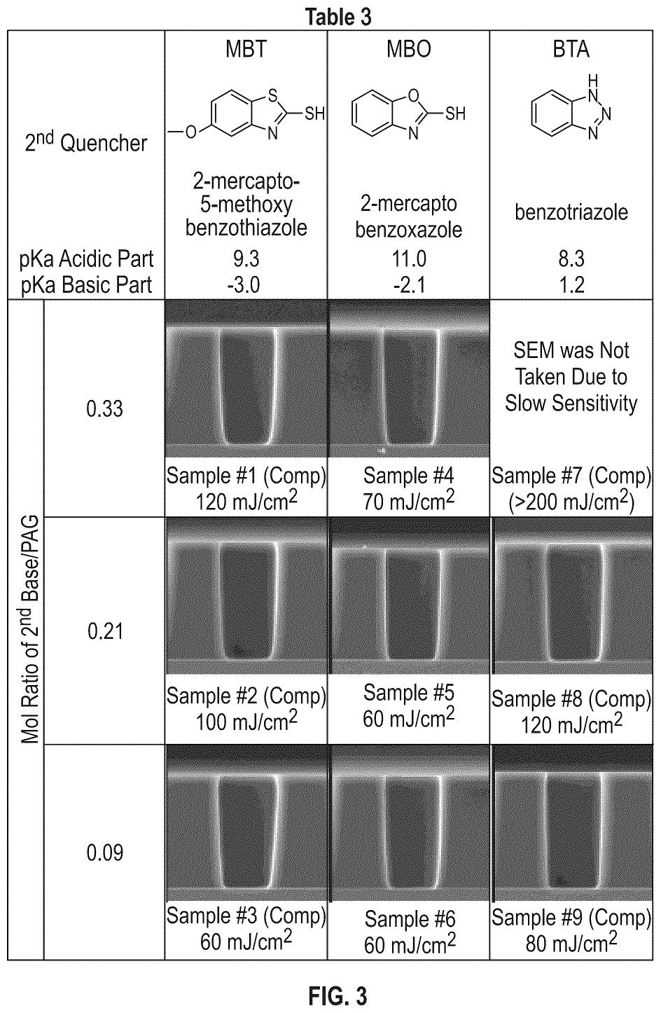

The formulations of Table 2 were used in photoresist compositions to determine which second base quencher produced the best sensitivity in a photoresist composition. The molar loading level of the second base quencher in the respective photoresist compositions was adjusted to be equivalent to each other when ratioed against total molar PAG loading in the photoresist composition. Sensitivity is defined as the exposure energy that gives an equivalent pattern size (or hole width) for each photoresist composition. A smaller number (amount) of exposure energy (i.e., a lower exposure energy for generating an equivalent pattern size) indicates that the sensitivity of the photoresist composition is greater when compared with a photoresist composition that uses larger amount for exposure energy. A more sensitive photoresist composition (one that uses less exposure energy) is better for energy consumption and for productivity. Table 3 in the FIG. 3 shows the sensitivity of 3 different photoresist compositions (that contain 2-mercapto 5-methoxy benzothiazole (MBT), benzotriazole (BTA) or 2-mercapto benzoxazole (MBO)) when used to produce a 25 micrometer hole. The 2-mercapto benzoxazole (MBO) shows the lowest energy exposure (and therefore the best sensitivity) of the three compounds when used in a photoresist composition.

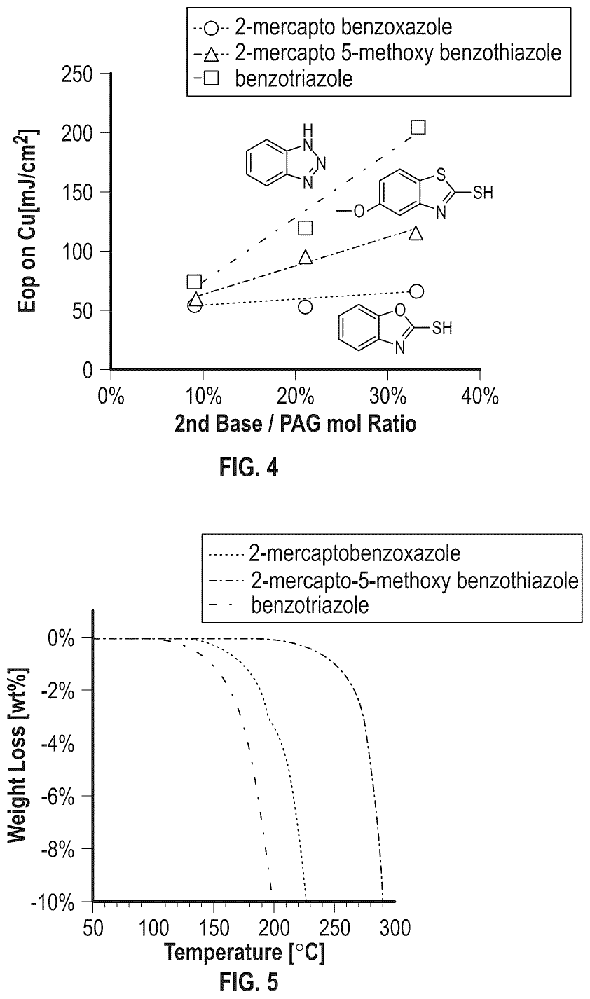

FIG. 4 is a graph that depicts the exposure energy (Eₒₚ) directed to the photoresist composition versus the molar ratio (of the second base quencher to the PAG) contained in each of the compositions. The FIG. 4 is a graphical representation of the exposure energy (Eₒₚ) shown in the FIG. 3 to produce the 25 micrometer hole. This plot therefore reflects the sensitivity of the photoresist composition. The 2-mercapto benzoxazole (MBO) shows the lowest energy exposure (and therefore the best sensitivity) of the three second base quencher compounds when used in a photoresist composition.

FIG. 5 is a depiction of weight loss of the each of the second base quenchers in a temperature range of 50° C. to the respective thermal degradation temperature as determined using thermogravimetric analysis. From the FIG. 5 it may be seen that the 2-mercaptobenzoxazole (MBO) displays better thermal stability than that of BTA or MBT.

### Example 3

This example was conducted to determine the effect of varying the ratio of the first base quencher to the second base quencher in the photoresist composition.

The amount of the first base quencher (Troger's base) was increased against the second base quencher (2-mercaptobenzoxazole) in order to evaluate its effect to pattern the profile (Error! Reference source not found.). The loading of the second base quencher (the 2-mercaptobenzoxazole) which displays a copper passivation effect was fixed at 0.053 pbw against 100 weight parts of polymer. The first base quencher was varied from 0.038 pbw to 0.050 pbw to 0.063 pbw. A cross sectional pattern profile of 25, 20 and 15 μm contact hole patterns were formed at exposure energy to achieve a nominal size (Eop) of 25 μm.

TABLE 4

| | Sample | Sample | Sample |
|---|---|---|---|
| Samples | #10A | #10B | #10C |
| Polymer | 100 pbw | | |
| PAG | NHNI-PFBS: 0.41 | | |
| | pbw/NHNI-TF: 0.29 pbw | | |
| 1^{st} Base | Troger's Base | | |
| | 0.038 pbw | 0.050 pbw | 0.063 pbw |
| 2^{nd} Base | 2-mercaptobenzoxazole | | |
| | 0.053 pbw | | |
| Total of 1^{st} | 0.30 | 0.33 | 0.36 |
| and 2^{nd} base/ | | | |
| PAG mol | | | |
| ratio | | | |

| | |
|---|---|
| Plasticizer | LUTONAL ™ M40 = |
| | 1.0 pbw |
| Solvents | PGMEA: 130 pbw, GBL: |
| | 3 pbw |

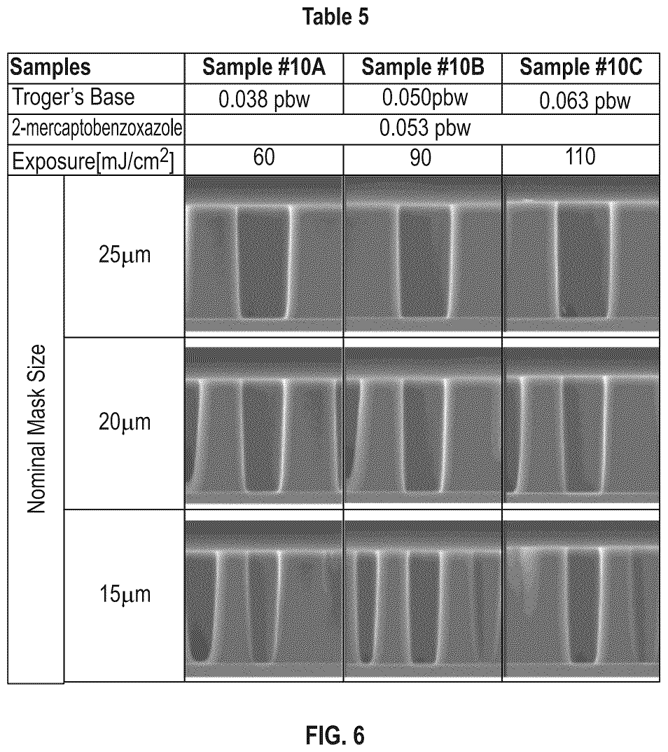

All of the samples showed narrow footing regardless of the angle of the sidewall as seen in the Table 5 shown in the FIG. 6.

1. A photoresist composition, comprising:
a polymer comprising a first repeat unit of formula (3) and a second repeat unit of formula (4): 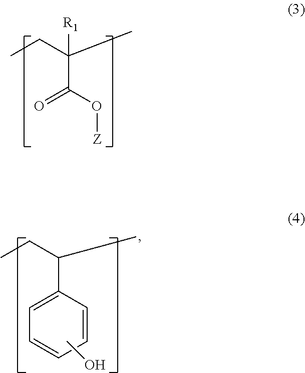
wherein: R₁ is a hydrogen atom or substituted or unsubstituted C₁-C₃ alkyl; Z is a non-hydrogen substituent comprising an acid-labile moiety;
a compound of formula (6): 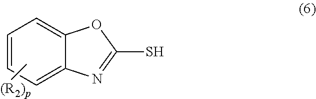
wherein: R₂ is independently C₁-C₃ alkyl or C₁-C₃ alkoxy; and p is an integer from 0 to 4;
a photoacid generator; and
a solvent.

2. The photoresist composition of claim 1, further comprising a base quencher that is different from the compound of formula (6).

3. The photoresist composition of claim 2, where the base quencher is selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino) propionate, 4-(p-tolyl) morpholine, or a combination thereof.

4. The photoresist composition of claim 2, where a mole ratio of the base quencher to the compound of formula (6) is 0.01:1 to 0.5:1.

5. The photoresist composition of claim 1, wherein the photoacid generator is selected from N-hydroxynaphthalimide trifluoromethanesulfonate, N-hydroxynaphthalimide perfluoro-1-butanesulfonate, N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy) phthalimide and N-hydroxysuccinimide perfluorobutanesulfonate.

6. The photoresist composition of claim 1, where a mole ratio of the compound of formula (6) to the photoacid generator is 0.01:1 to 0.5:1.

7. The photoresist composition of claim 1, where the compound of formula (6) is 2-mercaptobenzoxazole.

8. A photoresist composition comprising: (a) a polymer; (b) one or more photoacid generators; (c) a base quencher; (d) a mercaptobenzoxazole compound; and (e) a solvent;
wherein the polymer comprises the following two repeat units: 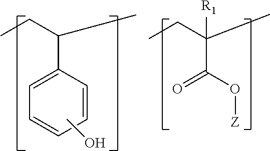
wherein R₁ is a hydrogen atom or substituted or unsubstituted C₁-C₃ alkyl; Z is a non-hydrogen substituent that provides an acid-labile moiety;
wherein the photoacid generator is selected from N-hydroxynaphthalimide trifluoromethanesulfonate, N-hydroxynaphthalimide perfluoro-1-butanesulfonate, N-hydroxynaphthalimide camphor-10-sulfonate, N-hydroxynaphthalimide 2-trifluoromethylphenylsulfonate, N-hydroxy-5-norbornene-2,3-dicarboximide perfluoro-1-butanesulfonate, N-(trifluoromethylsulfonyloxy) phthalimide and N-hydroxysuccinimide perfluorobutanesulfonate;
wherein the base quencher selected from N-diethyldodecanamide, 2,8-dimethyl-6H,12H-5,11-methanodibenzo[b,f][1,5]diazocine (Troger's Base), 1,1-dimethylethyl 4-hydroxypiperidine-1-carboxylate, N-allylcaprolactam, ethyl-3-(morpholino) propionate, 4-(p-tolyl)morpholine, or a combination thereof;
wherein the mercaptobenzoxazole compound is of formula (6): 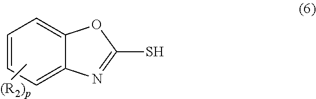
wherein: R₂ is independently C₁-C₃ alkyl or C₁-C₃ alkoxy; and p is an integer from 0 to 4; and
wherein the solid content of the photoresist composition is from 10 to 60 wt %.

9. The photoresist composition of claim 8, wherein the second base quencher is 2-mercaptobenzoxazole.

10. A process comprising:
(i) providing a substrate comprising a metal layer on a surface of the substrate;
(ii) forming a photoresist layer on the metal layer, wherein the photoresist layer is formed from a photoresist composition of claim 1;
(iii) patternwise exposing the photoresist layer to activating radiation; and
(iv) contacting the photoresist layer with an alkaline developing solution to remove exposed portions of the photoresist layer; and
(v) immersing the substrate in a metal plating solution and depositing a metal on the metal layer in the exposed portions of the photoresist layer.
